(19) United States
(12) Patent Application Publication
(10) Pub. No.: US 2014/0253169 A1
(43) Pub. Date: Sep. 11, 2014

(54) BURST NOISE IN LINE TEST

(71) Applicant: INTERNATIONAL BUSINESS MACHINES CORPORATION, Armonk, NY (US)

(72) Inventors: Kai D. Feng, Hopewell Junction, NY (US); Zhenrong Jin, Essex Junction, VT (US)

(73) Assignee: INTERNATIONAL BUSINESS MACHINES CORPORATION, Armonk, NY (US)

(21) Appl. No.: 13/788,125

(22) Filed: Mar. 7, 2013

(51) Int. Cl. G01R 31/26

(52) U.S. Cl. CPC G01R 31/2646
USPC 324/762.01

(57) ABSTRACT

A type of device (which can be deployed in a semiconductor manufacturing line) determining whether a device-under-test is generating burst noise. A transimpedance amplifier converts a current-based noise signal to a voltage based noise signal to apply the following tests aimed at determining the presence of burst noise: (i) sufficiently wide pulse width in the noise signal; (ii) sufficiently random pulse width in the noise signal; (iii) sufficiently wide pulse separation in the noise signal; (iv) sufficiently random pulse separation in the noise signal; and (v) sufficiently large pulse amplitude (or magnitude) in the noise signal.

### FIELD OF THE INVENTION

The present invention relates generally to the field of testing semiconductor devices, and more particularly to in line testing semiconductor devices for burst noise.

### BACKGROUND OF THE INVENTION

In operation, many semiconductor devices exhibit a known, and generally problematic, phenomenon known as burst noise, or popcorn noise. Burst noise can be especially problematic in diode and bipolar transistor portions of semiconductor devices.

The burst noise is usually characterized by the following: (i) the noise waveform is like a current pulse; (ii) the pulse width is wide up to the millisecond range; (iii) the pulse width is random; (iv) the pulse separation is as large as several tens of milliseconds, or longer; (v) the separation time between pulses is random; and/or (vi) the magnitude is higher than that of white noise by a factor of several times.

Usually, the cause of the burst noise is defect(s) introduced during the process of semiconductor manufacture. The presence, amount and/or magnitude of burst noise is sometimes used as an indicator of the semiconductor manufacture quality.

### SUMMARY

According to an aspect of the present invention, a testing device tests a semiconductor device to determine whether the semiconductor device generates burst noise. The testing device includes: a current-based noise signal receiving circuitry portion; a conversion circuitry portion; and a burst noise testing circuitry portion. The current-based noise signal receiving circuitry portion is structured, sized, shaped and/or electrically connectable to receive a current-based noise signal from the semiconductor device. The conversion circuitry portion is structured, sized, shaped and/or electrically connected to: (i) receive the current-based noise signal from the current-based noise signal receiving circuitry portion, and (ii) convert the current-based noise signal into a voltage-based noise signal. The burst noise testing circuitry portion is structured, sized, shaped and/or electrically connected to: (i) receive the voltage-based noise signal from the conversion circuitry portion, and (ii) test the voltage-based noise signal to determine if it meets at least one burst noise criterion.

According to a further aspect of the present invention, a testing device tests a semiconductor device to determine whether the semiconductor device generates burst noise. The testing device includes: a first burst noise testing circuitry portion; a second burst noise testing circuitry portion; a third burst noise testing circuitry portion; and a fourth burst noise testing circuitry portion. The first burst noise testing circuitry portion is structured and/or electrically connected to determine whether a pulse, of a noise signal from the semiconductor device, is sufficiently long to meet a minimum pulse duration burst noise criterion. The second burst noise testing circuitry portion is structured and/or electrically connected to determine whether a separation, between two pulses of the noise signal, is sufficiently long to meet a minimum pulse separation duration burst noise criterion. The third burst noise testing circuitry portion is structured and/or electrically connected to determine whether durations of at least two pulse durations, of the noise signal, are sufficiently different from each other to meet a minimum pulse duration randomness burst noise criterion. The fourth burst noise testing circuitry portion is structured and/or electrically connected to determine whether at least two separation durations, respectively between two pulses of the noise signal, are sufficiently different from each other to meet a minimum pulse separation randomness burst noise criterion.

According to a further aspect of the present invention, there is a method of testing a semiconductor device. The method includes the following steps (not necessarily in the following order): (i) manufacturing the semiconductor device on a manufacturing line; (ii) during the manufacturing step, receiving a noise signal from the semiconductor device by a testing device; and (iii) during the manufacturing step, testing the noise signal to determine if it meets at least one burst noise criterion.

### BRIEF DESCRIPTION OF THE SEVERAL VIEWS OF THE DRAWINGS

FIG. 1 is a schematic view of a first embodiment of an in line semiconductor test device according to the present invention;

FIG. 2 is a schematic view of a second embodiment of an in line semiconductor test device according to the present invention;

FIG. 3 is a timing diagram helpful in understanding the first and second embodiment test devices;

FIG. 4A is a schematic view of a portion of the first embodiment testing device;

FIG. 4B is a pulse diagram helpful in understanding circuitry of the portion of the first embodiment testing device shown in FIG. 4A;

FIG. 5A is a detailed schematic view of a portion of the first embodiment testing device;

FIG. 5B is a detailed schematic view of a portion of the first embodiment testing device;

FIG. 5C is a detailed schematic view of a portion of the first embodiment testing device;

FIG. 6A is a detailed schematic view of a portion of the first embodiment testing device;

FIG. 6B is a detailed schematic view of a portion of the first embodiment testing device;

FIG. 6C is a detailed schematic view of a portion of the first embodiment testing device;

FIG. 7 is a detailed schematic view of a portion of the first embodiment testing device; and

FIG. 8 is a simulation display of a simulation of the first embodiment testing device.

### DETAILED DESCRIPTION

This DETAILED DESCRIPTION section will be organized into sub-sections as follows: (i) General Comments; (ii) Embodiment(s) of the Present Invention; and (iii) Definitions.

### I. General Comments

At least some embodiments of the present invention make it possible to perform a test to detect burst noise in the environment of the semiconductor manufacturing line. This burst noise line test performed in the semiconductor manufacturing line will herein be referred to as an “in line test.” It is believed that in line tests are generally better than conventional off line burst noise tests because in line testing potentially: (i) reduces customer problems with semiconductor devices; (ii) enhances semiconductor device quality; and/or (iii) leads to time efficiency, cost efficiency and/or improved quality control of the manufacturing process.

Some embodiments of the present invention include circuitry that combines a transimpedance amplifier, a low frequency amplifier and an AC coupling with a large time constant. This combination of circuit elements serve to amplify the burst noise for burst noise testing purposes. The transimpedance amplifier effectively takes a noise-prone signal based on current (that is the noise signal itself from the device-under-test) and converts it into a voltage signal so that relevant characteristics of the signal can be easily and reliably measured and compared (for example, compared to various threshold values). The measurement and comparison of relevant characteristics of the converted, voltage-based signal reveals whether the noise-prone signal from the device-under-test meets predetermined criteria for burst noise. In this way, it is determined whether: (i) the device-under-test, being tested in an in line fashion, is, or is not, generating burst noise; and (ii) the “strength” of any detected burst noise. This facilitates in line quality control, timely scrapping of bad parts and the like.

Some exemplary embodiments of the present invention have improved circuitry for recognizing, or distinguishing, burst noise from the other type of noises. In some embodiments, this improved burst-noise-distinguishing circuitry includes digital filters for detection of: (i) pulse width; (ii) pulse separation; and/or (iii) degree of randomness of the time distribution of the pulses.

Different embodiments of the present invention may use different tests and/or different thresholds for a determination of whether the semiconductor-device-under-test generates burst noise. In a preferred testing circuitry embodiment of the present invention, which will be explained in detail in the following sub-section, the criterion and associated tests for burst noise are as follows: (i) sufficiently wide pulse width in the noise-prone signal; (ii) sufficiently random pulse width in the noise-prone signal; (iii) sufficiently wide pulse separation in the noise-prone signal; (iv) sufficiently random pulse separation in the noise-prone signal; and (v) sufficiently large pulse amplitude (or magnitude) in the noise-prone signal. For the sake of simplicity, the noise-prone signal from the semiconductor-device-under-test may sometimes be herein referred to simply as the “noise signal,” or, more specifically as “the current-based noise signal” or “the voltage-based noise signal,” depending upon whether the specific signal is upstream of the transimpedance amplifier (that is, the current-based signal) or downstream of the transimpedance amplifier (that is, the voltage-based noise signal).

### II. Embodiment(s) of the Present Invention

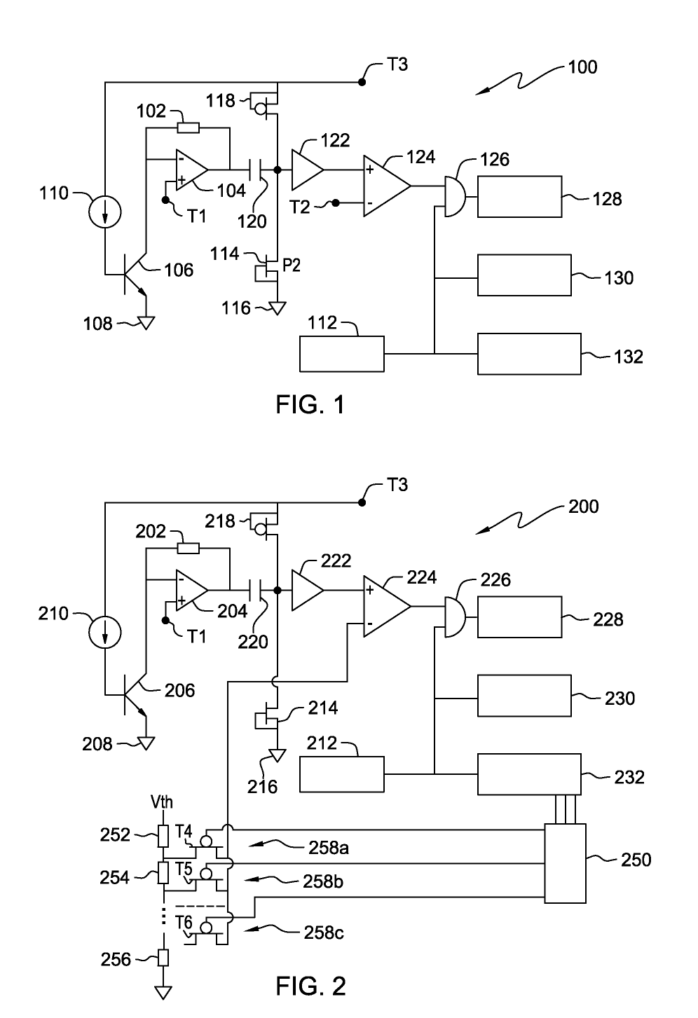

As shown in FIG. 1, fixed threshold burst noise in line semiconductor test device 100 includes: feedback resistor 102 (with a resistance value of Rf); transimpedance amplifier (also called U1) 104 (components 102 and 104, taken together, make up a “transimpedance amplifier,” but, for the sake of simplicity, amplifier 104 is sometimes referred to as the transimpedance amplifier); bipolar transistor under test (also called Q) 106; first ground 108; base current source (also called Ib) 110; on chip ring oscillator (also called U7) 112; Negative Channel Field Effect Transistor (NFET) 114; second ground 116; Positive Channel Field Effect Transistor (PFET) 118; capacitor 120; voltage amplifier (also called U1a) 122; voltage comparator (also called U2 Comp) 124; AND gate (also called U3 and) 126; duration match counter (also called U4) 128; period match counter (also called U5) 130; and test counter (also called U6) 132. Terminal voltage values are as follows: T1=Vc (collector voltage); T2=Vh; and T3=Vcc.

Operation of device 100 will now be discussed. Capacitor 120, PFET 118 and NFET 114 form an alternating current (AC) coupling characterized by a long time constant and a predetermined bias voltage. The functions of transimpedance amplifier 104 are: (i) the conversion from an input current to an output voltage; and (ii) to maintain Vc as the collector voltage. As shown in FIG. 1, operational amplifier 104 is electrically connected to feedback resistor 102 in the following ways: (i) at its output; and (ii) at its inverting input. The collector voltage of Q 106 will be maintained at the value Vc (that is, the voltage at terminal T1) because: (i) the voltage gain of operational amplifier 104 is very large; and (ii) the inverting input voltage and the non-inverting input voltage are very close.

The burst noise exists in the large collector current of Q. This is the “current-based noise signal” mentioned above. The AC coupling of capacitor 120, PFET 118 and NFET 114 provides for effective signal coupling between transimpedance amplifier 104 and voltage amplifier 122. The burst noise frequency is very low, which is why it is generally preferable to design the AC coupling circuitry 114, 118, 120 to have a large time constant.

As shown in FIG. 1, capacitor 120 is interposed between the output of transimpedance amplifier 104 and the input of voltage amplifier 122. Because of the operating frequency(ies), there will generally not be a large capacitance in the integrated circuits, and the resistance of the input of voltage amplifier 122 accounts for this characteristic. PFET 118 and the NFET 114 will operate in cut off mode, or the sub threshold mode. PFET 118 and NFET 114 are used for setting the input bias of voltage amplifier 122. This circuitry works to convert the current-based noise signal into the “voltage-based noise signal” mentioned above.

Voltage comparator 124 is a voltage comparator having threshold voltage value Vth. When the voltage at the positive input of voltage comparator 124 is greater than Vth, the output logic status is “high.” If the output of voltage comparator 124 is “high,” then AND gate 126 allows duration match counter 128 to count clock pulses generated in on chip ring oscillator 112. If the pulse count of duration match counter 128 reaches a predefined durational threshold during the interval of some noise, then counter 128 sends a matching signal to indicate that the noise duration is sufficient to meet a burst noise minimum duration criterion.

Period match counter 130 counts the clock pulses generated by chip ring oscillator 112 that occur in time between two rising edges of the output of voltage comparator 124. The count of counter 130 provides a value for the period of the noise. If the pulse count of counter 130 reaches a predefined period threshold, then counter 130 sends a signal to indicate that the noise period is sufficiently long to meet a burst noise minimum period criterion.

Chip ring oscillator 112 generates regular pulses at regular intervals to help control system timing. Test counter 132 counts the pulses from on chip ring oscillator 112 to determine when a burst noise test is completed. For example, in this embodiment the in line burst noise test is designed to last for a duration of 1 second per device-under-test.

As shown in FIG. 2, programmable threshold burst noise test device 200 includes: feedback resistor 202 (with a resistance value of Rf); operational amplifier (also called U1) 204 (components 202 and 204, taken together, form a transimpedance amplifier, but, for the sake of simplicity, operational amplifier 204 may be referred to as the transimpedance amplifier); bipolar transistor under test (also called Q) 206; first ground 208; base current source (also called Ib) 210; on chip ring oscillator (also called U7) 212; Negative Channel Field Effect Transistor (NFET) 214; second ground 216; Positive Channel Field Effect Transistor (PFET) 218; capacitor 220; voltage amplifier (also called U1a) 222; voltage comparator (also called U2 Comp) 224; AND gate (also called U3 and) 226; duration match counter (also called U4) 228; period match counter (also called U5) 230; test counter (also called U6) 232; M-decoder 250; resistors 252, 254, 256; and PFET array 258a,b,c. Terminal voltage values are as follows: T1=Vc (collector voltage); T3=Vcc; T4=Vt1; T5=Vt2; and T6=Vtk. The basic operation is similar to the fixed threshold device, discussed above.

In device 200, a most significant bit decoder (that is, M-decoder 250) is used to control the threshold voltages through PFET array 258. For example, the following pattern of successive runs may be performed with programmable device 200: (i) in the first run, occurring over the first second of testing, only PFET 258a (having a threshold voltage of Vt1) is turned on and applied at the negative input of voltage comparator 224; (ii) in the second run, occurring over the 2nd second of testing, only PFET 258b (having a threshold voltage of Vt2) is turned on and applied at the negative input of voltage comparator 224; and (iii) so on in a like manner.

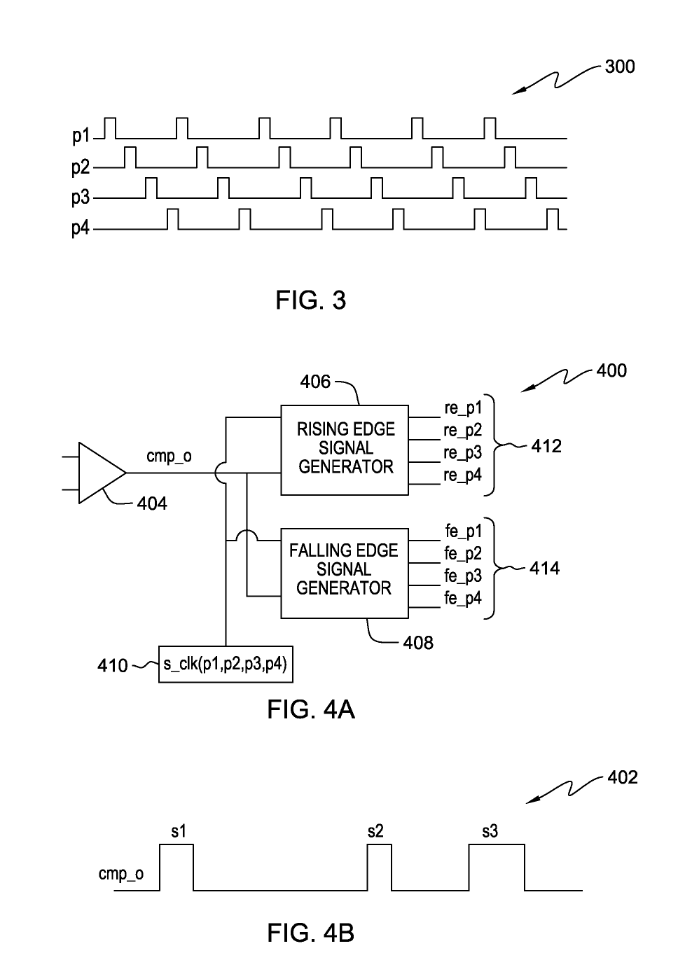

As shown in FIG. 3, system clock (s_clk) timing diagram 300 includes four pulse lines p1, p2, p3, and p4. Actions related to this timing diagram will now be described in the following paragraphs.

Actions occurring during p1 pulse intervals: (i) check if the contents in the counters of the pulse width and the pulse separation are larger than the respective predefined minimum threshold values for burst noise; and (ii) compare the current counter values pulse width and pulse separation to previous counter values (stored in a register, not shown in FIG. 3) for pulse width and pulse separation to determine if the pulse width and/or pulse separations are sufficiently random.

Actions occurring during p2 pulse intervals: (i) move the current counter values for pulse width and pulse separation to a register for storage (in this example, there is only storage for one previous value of pulse width and one previous value of pulse separation, but other embodiments may have more storage for more comprehensive determinations of randomness in width and/or separation); and (ii) count the number of the burst noise if the pulse meets the burst noise requirement.

Actions occurring during p3 pulse intervals: (i) reset counters for pulse width and pulse separation; and (ii) reset all status registers if status register reset conditions are met. The status register reset conditions are as follows: (i) pulse width is determined to be wide enough; (ii) current pulse width is not the same to that of last time; and (iii) pulse separation has been determined to be wide enough.

Actions occurring during the p4 intervals: (i) increment the counters.

As shown in FIGS. 4A and 4B, edge generator circuitry 400 generates the rising edges and falling edges for the pulses shown in timing diagram 300 (discussed above). Edge-related circuitry 400 (and a related diagram) includes: cmp_o timing diagram 402; voltage comparator 404; rising edge signal generator 406; falling edge signal generator 408; signal s_clk(p1,p2,p3,p4) 410; rising edge output signals 412; and falling edge output signals 414.

CMP_o timing diagram 402 shows a typical waveform for the output of voltage comparator 404. More specifically, there are three output signals: s1, s2, and s3. The definition of the pulse separation for s1/s2 is the time difference between the rising edge of s1 and the rising edge of s2. Similarly, the separation for s2/s3 is the time difference between rising edge of s2 and the rising edge of s3.

When a rising edge occurs in the output of voltage comparator 404 (that is, cmp_o), rising edge signal generator 406 generates rising edge output signals 412 (specifically, pulses re_p1, re_p2, re_p3 and re_p4). Rising edge output signals 412 are synchronized to signal s_clk (p1, p2, p3, p4) 410. When a falling edge occurs in cmp_o, falling edge signal generator 408 generates falling edge output signals 414 (specifically pulses fe_p1, fe_p2, fe_p3 and fe_p4) falling edge output signals 414 are synchronized to the signal s_clk (p1, p2, p3, p4) 410.

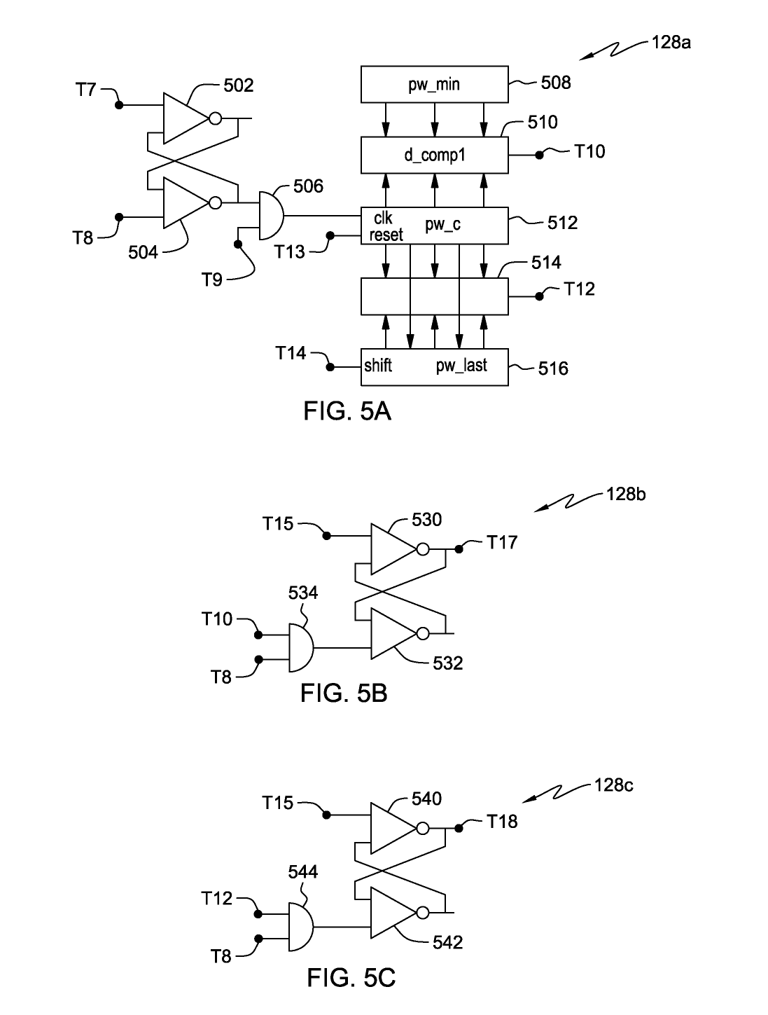

Duration match counter 128 (shown in block form in FIG. 1) will now be discussed in more detail with reference to FIGS. 5A, 5B and 5C. As shown in FIG. 5A, first portion 128a of duration match counter 128 includes: first NOR gate 502; second NOR gate 504; AND gate 506; pulse width minimum (or pw_min) block 508; first comparison (or d_comp1) block 510; pulse width counter (or pw_c) block 512; second comparison (or d_comp2) block 514; and pulse width last (or pw_last) block 516. As shown in FIG. 5B, second portion 128b of duration match counter 128 includes: first NOR gate 530; second NOR gate 532; and AND gate 534. As shown in FIG. 5C, third portion 128c of duration match counter 128 includes: first NOR gate 540; second NOR gate 542; and AND gate 544. The signal names used in FIGS. 5A to 5C are as follows: T7 is rising edge p1 (re_p1); T8 is falling edge p1 (fe_p1); T9 is s_clk p4; T10 is pw_g_t; T12 is pw_n_e; T13 is falling edge p3 (fe_p3); T14 is falling edge p2 (fe_p2); and T15 is rising edge p3 (re_p3).

As shown in FIG. 5A, NOR gates 502 and 504 form an R-S (reset-set) register. When a rising edge occurs in the comparator output cmp_o, the positive pulse re_p1 (that is, T7 in FIG. 5A) sets the output of NOR gate 504 at “high” so that AND gate will remain open. The pulse width counter at pw_c block 512 starts to count pulses in the signal s_clk_p4 (that is, T9 in FIG. 5A). When the falling edge occurs in cmp_o, fe_p1 (that is T8 in FIG. 5A) sets the output of NOR gate 504 at “low” so that AND gate 506 becomes blocked, which means that the pulse width counting of pulses in the s_clk_p4 signal (that is, T9 in FIG. 5A) by pw_c block 512 stops. When this counting stops, the content in pw_c block 512 provides a quantitative measure of the pulse width. Pw_c block 512 is reset by the falling edge pulse fe_p3 (that is, T13 in FIG. 5A).

Pulse width minimum block 508 is a register where a predefined minimum pulse width (that is, the burst noise minimum duration criterion, mentioned above) is stored.

D_comp1 block 510 is a digital comparator that compares the inputs from pw_min block 508 and pw_c block 512 to determine whether the burst noise minimum duration criterion is met for the semiconductor device being tested. More specifically, if the content of pw_c block 512 is greater than the burst noise minimum duration criterion stored in pw_min block 508, then the output pw_g_t (that is, T10 in FIG. 5A) is set to “high.” Otherwise, pw_g_t remains at “low” status. The purpose of this comparison is to check if the pulse width is greater than the minimum pulse width of a burst noise.

As shown in FIG. 5A, pw_last block 516 stores the pulse width of the previous pulse. The falling edge of P2 (that is, fe_p2, T14 in FIG. 5A) causes the content of pw_c block 512 to shift to pw_last block 516.

As shown in FIG. 5A, d_comp2 block 514 is a digital comparator. This digital comparator compares inputs respectively received from: (i) pw_c block 512; and (ii) pw_last block 516. If these inputs are not the same, then the output pw_n_e (that is, T12 in FIG. 5A) is set to “high,” but otherwise this output remains “low.” The purpose of the comparison is to determine whether the pulse width is random, which is another criterion for burst noise. In this embodiment, consecutive pulses and/or pulse separations are determined to be sufficiently random if they do not match exactly, but other embodiments may require consecutive pulses and/or pulse widths to have counts that are different over some threshold to be considered as sufficiently random to be considered as “burst noise.”

As shown in FIG. 5B, first and second NOR gates 530, 532 form a status register for pulse width. The rising edge pulse re_p3 signal (that is, T15 in FIG. 5B) works to reset the output pw_{—}1 of first NOR gate 530 (that is, T17 in FIG. 5B). If signal pw_g_t (that is, T10 in FIG. 5B) is at “high” when the pulse of fe_p1 (that is, T8 in FIG. 5B) occurs, then this condition will cause AND gate 534 to open, and this causes pw_{—}1 (that is, T17 in FIG. 5B) to be set “high.” When pw_{—}1 is set “high,” then this condition indicates the pulse width is greater than the minimum value for burst noise, thus qualifying the current pulse to potentially be counted as burst noise because it meets the minimum burst noise duration criterion.

As shown in FIG. 5C, first and second NOR gates 540, 542 form a status register for storing pulse width. The rising edge pulse of pulse p3, re_p3 (that is, T15 in FIG. 5C) resets the output pw_n (that is, T18 in FIG. 5C) of first NOR gate 540. If pw_n_e (that is, T12 in FIG. 5C) is “high” when the falling edge of P1, fe_p1 (that is, T8 in FIG. 5C), occurs, then this causes AND gate 544 to open, which, in turn, causes pw_n (that is T18 in FIG. 5C) to be set “high.” When pw_n is set “high,” then this indicates that the current pulse width measured is different from the previous measured pulse width value. This means that the pulses may qualify as burst noise because they meet a burst noise pulse separation randomness criterion.

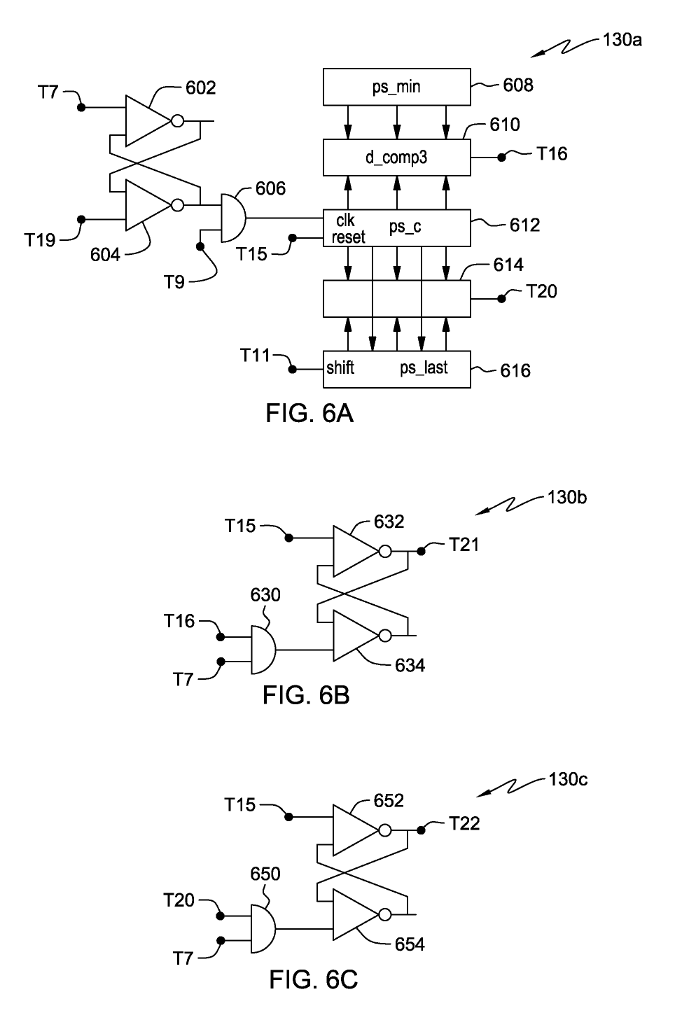

Period match counter (also sometimes called burst noise pulse separation block) 130, shown in block form in FIG. 1, will now be discussed in more detail with reference to FIGS. 6A, 6B and 6C. As shown in FIG. 6A, first portion 130a of period match counter 128 includes: first NOR gate 602; second NOR gate 604; AND gate 606; pulse separation minimum (or ps_min) block 608; third comparison (or d_comp3) block 610; pulse separation counter (or ps_c) block 612; fourth comparison (or d_comp4) block 614; and pulse separation last (or ps_last) block 616. As shown in FIG. 6B, second portion 130b of period match counter 130 includes: first NOR gate 632; second NOR gate 634; and AND gate 630. As shown in FIG. 6C, third portion 130c of period match counter 130 includes: first NOR gate 652; second NOR gate 654; and AND gate 650. The signal names used in FIGS. 6A to 6C are as follows: T7 is rising edge p1 (re_p1); T9 is s_clk p4; T11 is rising edge p2 (re_p2); T15 is rising edge p3 (re_p3); T16 is ps_g_t; T19 is Test_b; T20 is ps_n_e; T21 is ps_{—}1; and T22 is ps_n.

As shown in FIG. 6A, first and second NOR gates 602, 604 form a R-S register. During periods where there is no active testing occurring, Test_b (that is T19 in FIG. 6A) is set to “high,” which causes: (i) AND gate 606 to block the s_clk_p4 signal (that is, T9 in FIG. 6A); and (ii) pulse separation counter block will not count. If period match counter block 130 is to begin a test, then: (i) the Test_b signal (that is T19 in FIG. 6A) is set to “low;” (ii) when the first rising edge occurs, the re_p1 signal (that is T7 in FIG. 6A) sets the output of first NOR gate 602 at “high;” and (iii) ps_c block 612 starts to count the pulse in signal s_ckl_p4 (that is, T9 in FIG. 6A) until the Test_b is set “high” again.

As shown in FIG. 6A, ps_c block 612: (i) starts the counting s_clk_p4 (that is, T9 in FIG. 6A) pulses at the first rising edge of cmp_o; and (ii) is reset by the next rising edge pulse p3 (that is, T15 in FIG. 6A). In this way, the content of ps_c block 612 at the next occurrence of an re_p1 (that is, T7 in FIG. 6A) will represent time interval of pulse separation.

As shown in FIG. 6A, ps_min block 608 is a register where the predefined minimum pulse separation is stored.

As shown in FIG. 6A, third comparison block 610 is a digital comparator. The output of block 610 (that is ps_g_t, which is T16 in FIG. 6A) remains at “low,” unless the content of ps_c block 612 is greater than the content of ps_min block 608, in which case ps_g_t (that is, T16 in FIG. 6A) is set to “high.”

As shown in FIG. 6A, ps_last block 616 is a register where the previous measurement of pulse separation while a new pulse separation value is being measured. The rising edge of p2 pulse (that is, re_p2, which is T11 in FIG. 6A) shifts the content of block 612 to ps_last block 616. In other embodiments of the present invention there may be additional storage so that more than one pulse separation value can be stored at any given time in order to allow comparison of many pulse separation values.

As shown in FIG. 6A, fourth comparison block 614 is a digital comparator. Block 614 compares the contents of block 612 and block 616. If these values in blocks 612 and 616 are not identical (after block 612 has finished counting up the current pulse separation), then the output ps_n_e (that is T20 in FIG. 6A) is set to “high.” Otherwise, ps_n_e remains at “low.”

As shown in FIG. 6B, first and second NOR gates 632, 634 form a status register, which is reset by the rising edge of p3 pulse (that is, re_p3, which is T15 in FIG. 6B). If ps_g_t (that is, T16 in FIG. 6B) is at logic “high” when the next rising edge of p1 pulse (that is, re_p1, which is T7 in FIG. 6B), then the output signal ps_{—}1 (that is, T21 in FIG. 6B) is set at logic “high,” which indicates that the pulse separation is greater than the minimum value so that the two pulse set qualifies as potential burst noise under the minimum pulse separation burst noise criterion.

As shown in FIG. 6C, first and second NOR gates 652, 654 form a status register, which is reset by the rising edge of p3 pulse (that is, re_p3, which is t15 in FIG. 6C). If the ps_n_e signal (that is, T20 in FIG. 6C) and the rising edge of p1 signal (that is, re_p1, which is T7 in FIG. 6C) are both “high,” then output ps_n (that is, T22 in FIG. 6C) is set at “high,” which indicates that: (i) the current pulse separation is not the same as the previous pulse separation; and (ii) the pulse set qualifies as potential burst noise under the burst noise randomness criterion.

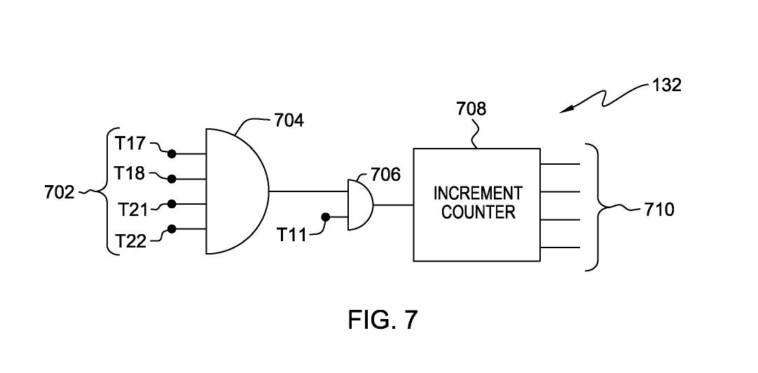

FIG. 7 shows a detailed schematic of test counter 132 (previously discussed in connection with FIG. 1), which includes: input signal set 702 (including T17, T18, T21, T22, discussed above); first AND gate 704; second AND gate 706; increment counter 708; and output signal set 710. As shown in FIG. 7, when the signals of input signal set 702 are all at “high,” then increment counter 708 will be incremented when the rising edge of p2 pulse signal (that is, re_p2, which is T11 in FIG. 6C) occurs.

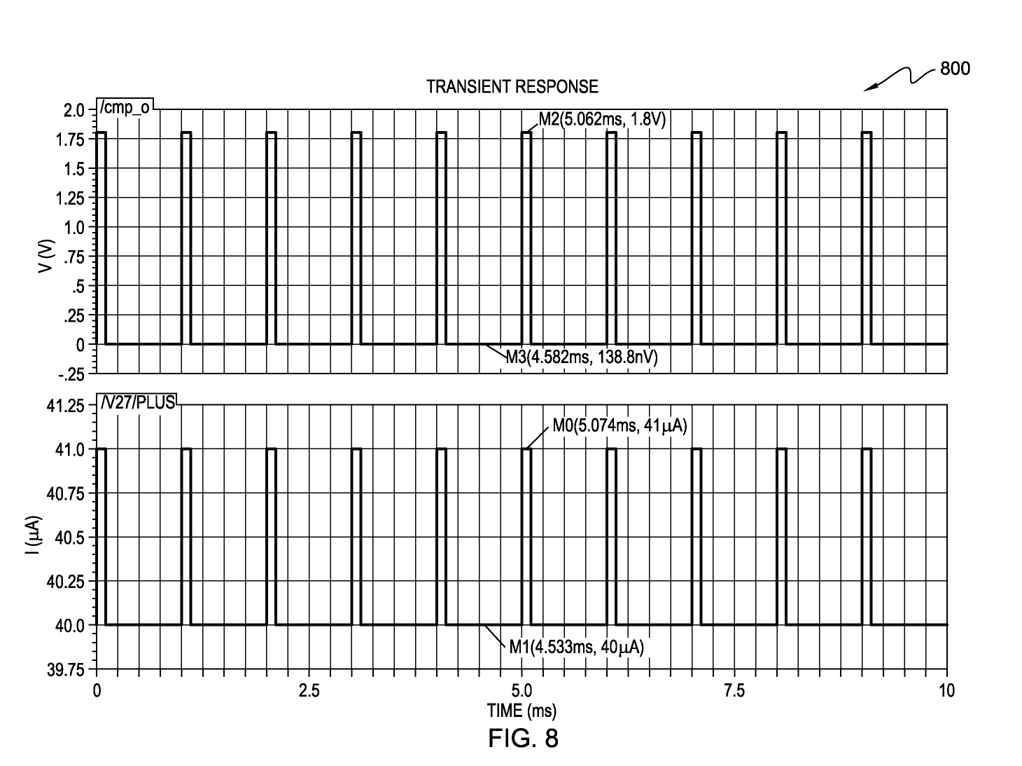

An analog front end, corresponding to the foregoing embodiment of the present invention, was simulated in Spectre. (Note: the term(s) “Spectre” may be subject to trademark rights in various jurisdictions throughout the world and the term(s) are used here only in reference to the products or services properly denominated by the marks to the extent that such trademark rights may exist). Screenshot 800 of FIG. 8 shows the waveforms of the input burst noise current (the burst noise waveform is also called Random Telegraph Signal waveform) and voltage comparator output signal cmp_o. This simulation demonstrated that an analog front section according to the present invention can detect delta RTS current of 1 micro-Ampere (μA) (that is, RTS jumps to 41 μA from 40 μA).

### III. Definitions

present invention: should not be taken as an absolute indication that the subject matter described by the term “present invention” is covered by either the claims as they are filed, or by the claims that may eventually issue after patent prosecution; while the term “present invention” is used to help the reader to get a general feel for which disclosures herein that are believed as maybe being new, this understanding, as indicated by use of the term “present invention,” is tentative and provisional and subject to change over the course of patent prosecution as relevant information is developed and as the claims are potentially amended.

embodiment: see definition of “present invention” above—similar cautions apply to the term “embodiment.”

and/or: non-exclusive or; for example, A and/or B means that: (i) A is true and B is false; or (ii) A is false and B is true; or (iii) A and B are both true.

What is claimed is:

1. A testing device for testing a semiconductor device to determine whether the semiconductor device generates burst noise, the testing device comprising:
a current-based noise signal receiving circuitry portion;
a conversion circuitry portion; and
a burst noise testing circuitry portion;
wherein:
the current-based noise signal receiving circuitry portion is structured, sized, shaped and/or electrically connectable to receive a current-based noise signal from the semiconductor device;
the conversion circuitry portion is structured, sized, shaped and/or electrically connected to: (i) receive the current-based noise signal from the current-based noise signal receiving circuitry portion, and (ii) convert the current-based noise signal into a voltage-based noise signal; and
the burst noise testing circuitry portion is structured, sized, shaped and/or electrically connected to: (i) receive the voltage-based noise signal from the conversion circuitry portion, and (ii) test the voltage-based noise signal to determine if it meets at least one burst noise criterion.

2. The testing device of claim 1 wherein the conversion circuitry portion includes at least one transimpedance amplifier.

3. A testing device for testing a semiconductor device to determine whether the semiconductor device generates burst noise, the testing device comprising:
a first burst noise testing circuitry portion;
a second burst noise testing circuitry portion;
a third burst noise testing circuitry portion; and
a fourth burst noise testing circuitry portion;
wherein:
the first burst noise testing circuitry portion is structured and/or electrically connected to determine whether a pulse, of a noise signal from the semiconductor device, is sufficiently long to meet a minimum pulse duration burst noise criterion;
the second burst noise testing circuitry portion is structured and/or electrically connected to determine whether a separation, between two pulses of the noise signal, is sufficiently long to meet a minimum pulse separation duration burst noise criterion;
the third burst noise testing circuitry portion is structured and/or electrically connected to determine whether durations of at least two pulse durations, of the noise signal, are sufficiently different from each other to meet a minimum pulse duration randomness burst noise criterion; and
the fourth burst noise testing circuitry portion is structured and/or electrically connected to determine whether at least two separation durations, respectively between two pulses of the noise signal, are sufficiently different from each other to meet a minimum pulse separation randomness burst noise criterion.

4. The testing device of claim 3 further comprising:
a fifth burst noise testing circuitry portion;
wherein:
the fifth burst noise testing circuitry portion is structured and/or electrically connected to determine whether at least one pulse, of a noise signal from the semiconductor device, is sufficiently large in amplitude to meet a minimum pulse amplitude burst noise criterion.

5. The testing device of claim 4 further comprising:
a determination logic portion for determining that the noise signal contains burst noise on condition that all of the following criteria have been determined to be met: (i) the minimum pulse duration burst noise criterion, (ii) the minimum pulse separation duration burst noise criterion, (iii) the minimum pulse duration randomness burst noise criterion, (iv) the minimum pulse separation randomness burst noise criterion, and (v) the minimum pulse amplitude burst noise criterion.

6. The testing device of claim 3 further comprising:
a noise signal receiving circuitry portion is structured, sized, shaped and/or electrically connectable to receive the noise signal from the semiconductor device while the semiconductor device is under manufacture in a manufacturing line.

7. The testing device of claim 3 further comprising:
a conversion circuitry portion structured and/or electrically connectable to: (i) receive the noise signal as a current-based noise signal from the semiconductor device, and (ii) convert the noise signal to a voltage-based noise signal corresponding to the current-based noise signal.

8. A method of testing a semiconductor device, the method comprising the following steps:
manufacturing the semiconductor device on a manufacturing line;
during the manufacturing step, receiving a noise signal from the semiconductor device by a testing device; and
during the manufacturing step, testing the noise signal to determine if it meets at least one burst noise criterion.

9. The method of claim 8 wherein the testing step includes the following sub-step:
determining whether a pulse, of the noise signal, is sufficiently long to meet a minimum pulse duration burst noise criterion.

10. The method of claim 8 wherein the testing step includes the following sub-step:
determining whether a separation, between two pulses of the noise signal, is sufficiently long to meet a minimum pulse separation duration burst noise criterion.

11. The method of claim 8 wherein the testing step includes the following sub-step:
determining whether durations of at least two pulse durations, of the noise signal, are sufficiently different from each other to meet a minimum pulse duration randomness burst noise criterion.

12. The method of claim 8 wherein the testing step includes the following sub-step:
determining whether at least two separation durations, respectively between two pulses of the noise signal, are sufficiently different from each other to meet a minimum pulse separation randomness burst noise criterion.

13. The method of claim 8 wherein the testing step includes the following sub-step:
determining whether at least one pulse, of a noise signal from the semiconductor device, is sufficiently large in amplitude to meet a minimum pulse amplitude burst noise criterion.
